(19) United States
(12) Patent Application Publication
(10) Pub. No.: US 2013/0096864 A1
(43) Pub. Date: Apr. 18, 2013

(54) APPARATUS FOR CALIBRATING TEST VALUE OF CURRENT

(71) Applicants: YUN BAI, Shenzhen City (CN); QI-YAN LUO, Shenzhen City (CN); SONG-LIN TONG, Shenzhen City (CN)

(72) Inventors: YUN BAI, Shenzhen City (CN); QI-YAN LUO, Shenzhen City (CN); SONG-LIN TONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/600,103

(22) Filed: Aug. 30, 2012

(30) Foreign Application Priority Data
Oct. 12, 2011 (CN) 201110308156.2

(51) Int. Cl. G01R 35/04; G06F 19/00

(52) U.S. Cl. 702/107

(57) ABSTRACT

An apparatus is configured for calibrating a test value of an output current of a digital power supply. The power supply has a control chip configured for detecting and outputting the test value of the output current. The apparatus includes a keyboard circuit, a digital potentiometer and a controller. The keyboard circuit is configured for inputting an actual value of the output current. The digital potentiometer is electronically connected to the control chip. The controller receives a test value and the actual value of the output current respectively from the control chip and the keyboard, determines whether the test value is equivalent to the actual value, adjusts the test value of the output current by adjusting an effective resistance of the digital potentiometer until the test value equals the actual value, and outputs the effective resistance of the digital potentiometer when the test value equals the actual value.

### BACKGROUND

1. Technical Field

The exemplary disclosure generally relates to calibration apparatuses; and particularly to apparatus for calibrating test value of output current of a digital power supply.

2. Description of Related Art

Digital power supplies are usually used to power a central processing unit and computer memory. The digital power supply may include a control chip and a display. The control chip detects an output current of the digital power supply and controls the display to display test value of the output current. Since the control chip detects the test value of the output current by sampling an analog output current of the digital power supply, the test value of the output current is usually different from the actual value of the output current. The control chip may have two connection pins connected in series with a correction resistor. The correction resistor is used to make the test value consistent with the actual value of the output current. The correction resistor is selected manually, that is, a tester connects different resistors between the connecting pins until gets a resistor with suitable resistance, which cooperatively works with the control chip to make the test value equals the actual value.

However, the aforementioned method to choose the suitable resistor is time-consuming and inconvenient.

Therefore, there is room for improvement within the art.

### BRIEF DESCRIPTION OF THE DRAWINGS

Many aspects of the embodiments can be better understood with reference to the drawings. In the drawings, the emphasis is placed upon clearly illustrating the principles of the disclosure.

FIG. 1 is a block diagram of a digital power supply, an electronic load, and an apparatus for calibrating test values of an output current of the digital power supply, according to an exemplary embodiment.

FIG. 2 is a circuit diagram of a controller, a communication circuit, and a keyboard circuit of the apparatus shown in FIG. 1.

FIG. 3 is a circuit diagram of a digital potentiometer and a temperature compensation circuit of the apparatus, and a control chip of the digital power supply shown in FIG. 1.

### DETAILED DESCRIPTION

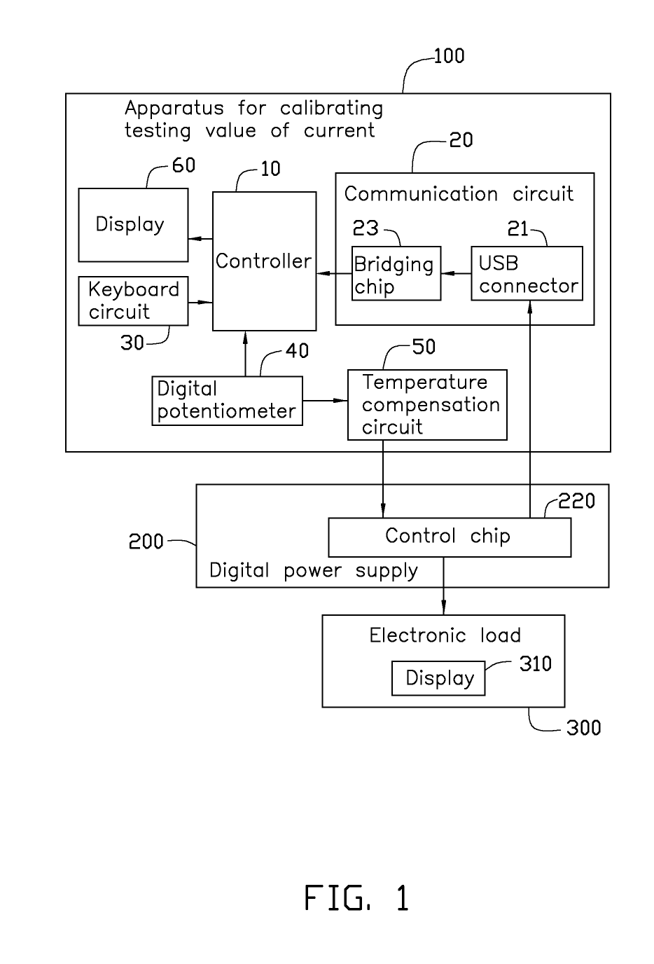

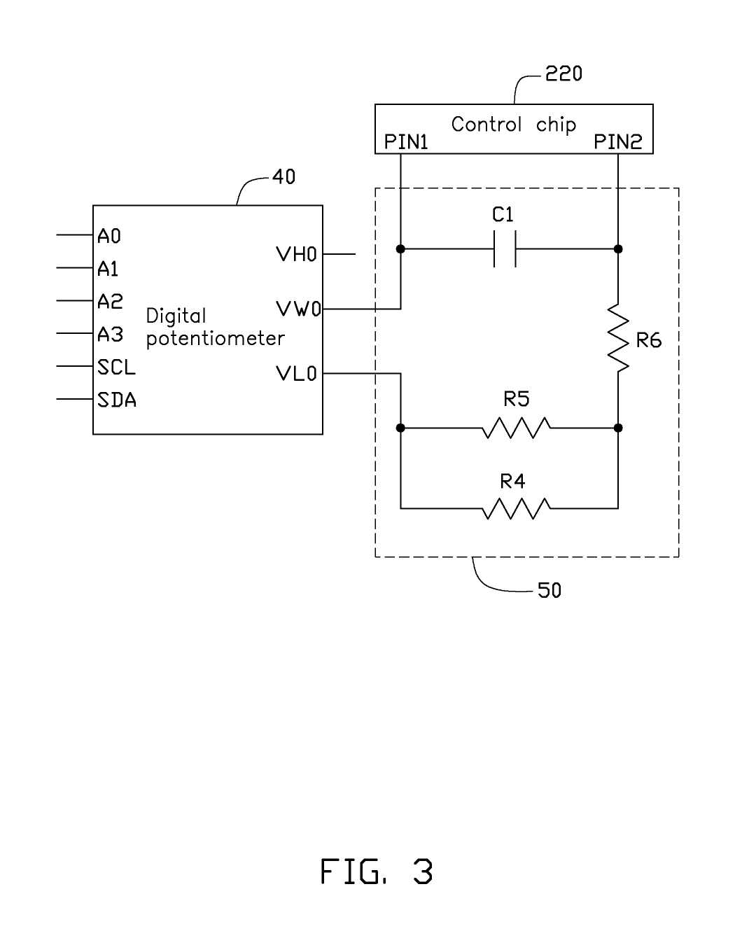

FIG. 1 is a block diagram of a digital power supply 200, an electronic load 300, and an apparatus for calibrating test values of an output current of a digital power supply 200, according to an exemplary embodiment. The digital power supply 200 is configured for driving the electronic load 300. The digital power supply 200 includes a control chip 220 electronically connected to the electronic load 300. The control chip 220 detects an output current of the digital power supply 200, that is, the current flowing through the electronic load 300. In the exemplary embodiment, the digital power supply 200 is used in a computer, the test values of the output current detected by the control chip 220 are transmitted to the apparatus 100 via a universal serial bus (USB) connector (not shown) of the computer. The control chip 220 includes a first calibration pin PIN1 and a second calibration pin PIN2 (shown in FIG. 3). The test value of the output current of the digital power supply 200 can be adjusted by connecting a current correction resistor between the first and second calibration pins PIN and PIN2.

The electronic load 300 includes a display 310. The electronic load 300 automatically detects an actual value of the output current flowing through the electronic load 300, and controls the display 310 to display the actual value of the output current.

The apparatus 100 includes a controller 10, a communication circuit 20, a keyboard circuit 30, a digital potentiometer 40, a temperature compensation circuit 50, and a display 60. The controller 10 obtains the test value of the output current via the communication circuit 20, and obtains the actual value of the output current displayed by the display 310 via the keyboard circuit 30. The digital potentiometer 40 is electronically connected between the first and second calibration pins PIN1 and PIN2 of the control chip 220. The controller 10 determines whether the test value is equivalent to the actual value, adjusts an effective resistance of the digital potentiometer 40 connected between the first and second calibration pins PIN1 and PIN2 of the control chip 220 until the test value is equivalent to the actual value, and outputs the effective resistance of the digital potentiometer 40 to the display 60.

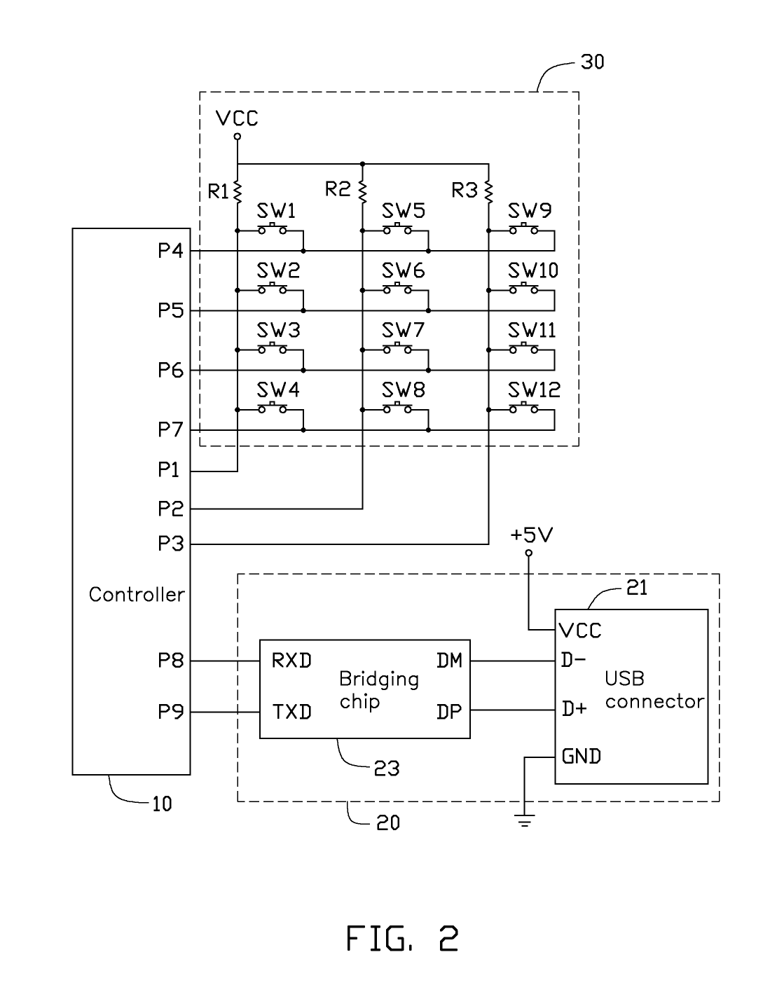

FIG. 2 is a circuit diagram of the controller 10, the communication circuit 20, and the keyboard circuit 30 of the apparatus 100 shown in FIG. 1. The controller 10 includes seven keyboard connecting pins P1-P7, and two test value input pins P8-P9. The keyboard connecting pins P1-P7 are electronically connected to the keyboard circuit 30 to receive the actual value of the output current. The test value input pins P8-P9 are electronically connected to the communication circuit 20 to receive the test value of the output current.

The communication circuit 20 includes a USB connector 21 and a bridging chip 23. The USB connector 21 receives the test value of the output current from the control chip 220 via the USB connector of the computer. A power pin VCC of the USB connector 21 is electronically connected to a power supply, such as a +5V power supply for example. A ground pin of the USB connector 21 is grounded.

The bridging chip 23 includes a first bridging pin DP, a second bridging pin DM, a series input pin RXD, and a series output pin TXD. The first and second bridging pins DP and DM are respectively connected to a positive differential signal pin D+ and a negative differential signal pin D− of the USB connector 21. The series input pin RXD and the series output pin TXD are respectively connected to the test value input pins P8 and P9. The bridging chip 23 is configured for transforming data formats between the USB connector 21 and the controller 10. In detail, the bridging chip 23 is configured for transforming differential data transmitted from the USB connector 21 to series data, which is then forwarded to the controller 10. Thus, the controller 10 receives the test value of the output current from the control chip 220 via the bridging chip 22 and the USB connector 21. In one embodiment, the bridging chip 22 is a PL2303 type made by TEXAS INSTRUMENTS.

In the exemplary embodiment, the keyboard circuit 30 includes twelve keys SW1-SW12. The keys SW1-SW12 and the keyboard connecting pins P1-P7 together form a 4×3 keyboard array. In detail, the keyboard connecting pins P1-P3 are electronically connected to a power supply labeled as VCC in FIG. 2 via current limiting resistors R1-R3 respectively. A terminal of the keys SW1-SW4 are electronically connected to a node formed between the keyboard connecting pin P1 and the current limiting resistor R1, the other terminal of the keys SW1-SW4 are electronically connected to the keyboard connecting pins P4-P7 respectively. A terminal of the keys SW5-SW8 are electronically connected to the a node formed between the keyboard connecting pin P2 and the current limiting resistor R2, the other terminal of the keys SW5-SW8 are electronically connected to the keyboard connecting pins P4-P7 respectively. A terminal of the keys SW9-SW12 are electronically connected to the a node formed between the keyboard connecting pin P3 and the current limiting resistor R3, the other terminal of the keys SW9-SW12 are electronically connected to the keyboard connecting pins P4-P7 respectively. The controller 10 scans the keyboard array to determine which key is pressed down in a way that is known to a person skilled in the art, so the determining process and method are not described in detail.

FIG. 3 is a circuit diagram of the digital potentiometer 40 and the temperature compensation circuit 50 of the apparatus 100, and a control chip 220 of the digital power supply 200 shown in FIG. 1. The digital potentiometer 40 includes a clock pin SCL, a data pin SDA, a wiper pin VW0, a first connecting pin VH0, and a second connecting pin VL0. The controller 10 communicates serially with the digital potentiometer 40 via the clock pin SCL and the data pin SDA, to adjust the effective resistance of the digital potentiometer 40. Since the clock pin SCL and the data pin SDA are connected to the controller 10 in a well-known way, the connection circuit between the controller 10 and the clock pin SCL, the data pin SDA are not shown in the FIGS. 1-3. The wiper pin VW0 has a wiper output, and is electronically connected to the first calibration pin PIN1 of the control chip 220. The first connecting pin VH0 is not connected, and the second connecting pin VL0 is electronically connected to the second calibration pin PIN2 via the temperature compensation circuit 50. In the exemplary embodiment, the type of the digital potentiometer 40 is X9241 made by XICOR, and includes four variable resistors.

The temperature compensation circuit 50 includes a temperature compensation resistor R4, a first resistor R5, a second resistor R6, and a filter capacitor C1. The temperature compensation resistor R4 is electronically connected to the first resistor R5 in parallel. A node formed between the temperature compensation resistor R4 and the first resistor R5 is electronically connected to the second connecting pin VL0 of the digital potentiometer 40, the other node formed between the temperature compensation resistor R4 and the first resistor R5 is electronically connected to the second calibration pin PIN2 of the control chip 220 via the second resistor R6. The filter capacitor C1 is electronically connected between the first and second calibration pins PIN1 and PIN2. The temperature compensation circuit 50 is configured for compensating the resistance changes of the components in the digital potentiometer 40 caused by the changes of the temperature. For example, the digital potentiometer 40 has a positive temperature characteristic, and the temperature compensation resistor R4 has a negative temperature characteristic. When the environmental temperature increases, the effective resistance of the digital potentiometer 40 increases accordingly, while the resistance of the temperature compensation resistor R4 decreases to compensate the resistance increment of the digital potentiometer, thereby correspondingly increase the precision of the apparatus 100.

Referring again to FIG. 1, the display 60 connected to the controller 10 in a well-known way, thus the connection circuits between the display 60 and the controller 10 are not shown in FIGS. 1-3. The display 60 displays the effective resistance value of the digital potentiometer 40 under the control of the controller 10. Then the controller 10 detects that the actual value of the output current equals to the test value of the output current, the controller 10 records the effective resistance value of the digital potentiometer 40, and controls the display 40 to display the effective resistance value. Therefore, a tester can easily determine a suitable resistance of the current correction resistor, and the tester can remove the apparatus 100 from the digital power supply 200, and connected the current correction resistor with suitable resistance between the first and second calibration pins PIN1 and PIN2.

The working process of the apparatus 100 can be carried out by, but is not limited to, the following steps. The controller 10 sets the effective resistance of the digital potentiometer 40. At this time, the digital potentiometer 40 preferably has a small resistance. The controller 10 then receives a test value of the output current of the digital power supply 200 via the communication circuit 20, and receives an actual value of the output current via the keyboard circuit 30. For example, a tester can input the actual value of the output current by pressing the keys. The controller 10 determines whether the test value is equivalent to the actual value. If the test value is not equal to the actual value, the controller 10 increases the effective resistance of the digital potentiometer 40, and the apparatus 100 repeats the aforementioned process until the test value and the actual value of the output current are the same. At this time, the digital potentiometer 40 can be used as a current correction resistor of the digital power supply 200. In addition, the controller 10 controls the display 60 to display the effective resistance value of the digital potentiometer 40. The tester can remove the apparatus 100 from the digital power supply 200, and connected the current correction resistor with suitable resistance between the first and second calibration pins PIN1 and PIN2. Therefore, the apparatus 100 can improve calibration efficiency.

The exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments.

What is claimed is:

1. An apparatus for calibrating a test value of an output current of a digital power supply comprising control chip configured for detecting the test value of the output current outputted to a load, the apparatus comprising:
a keyboard circuit configured for inputting an actual value of the output current;
a digital potentiometer electronically connected to the control chip; and
a controller electronically connected to the digital potentiometer, the keyboard circuit, and the control chip; the controller receiving a test value and the actual value of the output current respectively from the control chip and the keyboard, determining whether the test value is equivalent to the actual value, adjusting the test value of the output current by adjusting an effective resistance of the digital potentiometer until the test value equals the actual value, and outputting the effective resistance of the digital potentiometer when the test value equals the actual value.

2. The apparatus of claim 1, further comprising a display electronically connected to the controller, wherein the display displays the effective resistance of the digital potentiometer outputted from the controller.

3. The apparatus of claim 1, wherein the digital potentiometer comprises a wiper pin and a connecting pin, the wiper pin and the connecting pin are electronically connected to the control chip, and the wiper pin has a wiper output.

4. The apparatus of claim 3, wherein the digital potentiometer further comprises a clock pin and data pin, the data pin and the clock pin are electronically connected to the controller, the controller communicate serially with the clock pin and the data pin to adjust the effective resistance of the digital potentiometer.

5. The apparatus of claim 3, further comprising a temperature compensation circuit electronically connected between the digital potentiometer and the control chip, the temperature compensation circuit compensating the resistance changes of the digital potentiometer caused by environmental temperature changes.

6. The apparatus of claim 5, wherein the temperature compensation circuit comprises a temperature compensation resistor, a first resistor connected to the temperature resistor in parallel, and a second resistor, a node between the temperature compensation resistor and the first is electronically connected to the connecting pin of the digital potentiometer, the other node between the temperature compensation resistor and the first resistor is electronically connected to the control chip via the second resistor.

7. The apparatus of claim 6, wherein the temperature compensation circuit further comprises a filter capacitor electronically connected between a node between the second resistor and the control chip, and a node between a node between the wiper pin of the digital potentiometer and the control chip.

8. The apparatus of claim 1, further comprising a communication circuit, which comprises a Universal Serial Bus (USB) connector electronically connected between the control chip and the controller, the USB connector transmits the test value from the control chip to the controller.

9. The apparatus of claim 8, wherein the communication chip further comprises a bridging chip electronically connected between the controller and the USB connector, the bridging chip transforming differential data transmitted from the USB connector to series data, which is outputted to the controller.
